(19) United States
(12) Patent Application Publication
(10) Pub. No.: US 2012/0097226 A1
(43) Pub. Date: Apr. 26, 2012

(54) SOLAR CELL AND METHOD OF MANUFACTURING THE SAME

(75) Inventors: HOON HA JEON, Suwon-si (KR); Min Seok OH, Yongin-si (KR); NAMKYU SONG, Cheonan-si (KR); MIN PARK,, Seoul (KR); YEONIK JANG, Seoul (KR); Yun-Seok LEE, Seoul (KR); Cho-Young LEE, Suwon-si (KR)

(73) Assignee: SAMSUNG ELECTRONICS CO., LTD, Suwon-si (KR)

(21) Appl. No.: 13/159,725

(22) Filed: Jun. 14, 2011

(30) Foreign Application Priority Data
Oct. 26, 2010 (KR) 10-2010-0104719

(51) Int. Cl. H01L 31/06; H01L 31/0352

(52) U.S. Cl. 136/255; 438/87; 438/96; 257/E31.037

(57) ABSTRACT

A solar cell includes a semiconductor substrate including a first conductive type, a first amorphous silicon thin film layer disposed on the semiconductor substrate and a second amorphous silicon thin film layer including a second conductive type and disposed on the first amorphous silicon thin film layer. The first amorphous silicon thin film layer includes a first intrinsic silicon thin film layer, a second intrinsic silicon thin film layer facing the semiconductor substrate while interposing the first intrinsic silicon thin film layer therebetween and a first low concentration silicon thin film layer including the second conductive type and disposed between the first intrinsic silicon thin film layer and the second intrinsic silicon thin film layer.

This application claims priority to Korean Patent Application No. 10-2010-0104719, filed on Oct. 26, 2010, and all the benefits accruing therefrom under 35 U.S.C. §119, the content of which in its entirety is herein incorporated by reference.

### BACKGROUND OF THE INVENTION

1. Field of the Invention

The present invention relates to a solar cell and a method of manufacturing the solar cell. More particularly, the present invention relates to a solar cell having an improved photoelectric conversion efficiency and a method of manufacturing the solar cell.

2. Description of the Related Art

A solar cell is a device typically used to convert solar energy into electrical energy. Generally, to cause a photoelectric effect, the solar cell includes a semiconductor layer that absorbs the solar energy provided from an external source. Often, within the semiconductor layer, a p-type semiconductor layer is coupled with an n-type semiconductor layer. Alternatively, the semiconductor layer includes an intrinsic semiconductor layer disposed between the p-type semiconductor layer and the n-type semiconductor layer.

Since an amount of electrical power generated by the solar cell at least partially depends on a photoelectric conversion efficiency of the solar cell, various research has been conducted in this field in order to improve the amount of generated electrical power. Thus, an improvement in photoelectric conversion efficiency is desired in the art.

### BRIEF SUMMARY OF THE INVENTION

Exemplary embodiments of the present invention provide a solar cell having an improved photoelectric conversion efficiency.

Exemplary embodiments of the present invention provide a method of manufacturing the solar cell.

According to an exemplary embodiment, a solar cell includes a semiconductor substrate including a first conductive type, a first amorphous silicon thin film layer disposed on the semiconductor substrate and a second amorphous silicon thin film layer including a second conductive type and disposed on the first amorphous silicon thin film layer. The first amorphous silicon thin film layer includes a first intrinsic silicon thin film layer, a second intrinsic silicon thin film layer facing the semiconductor substrate while interposing the first intrinsic silicon thin film layer therebetween and a first low concentration silicon thin film layer including the second conductive type and disposed between the first intrinsic silicon thin film layer and the second intrinsic silicon thin film layer.

According to an exemplary embodiment, a method of manufacturing a solar cell is provided as follows. A first amorphous silicon thin film layer is formed on a first surface of a semiconductor substrate including a first conductive type and a second amorphous silicon thin film layer including a second conductive type is formed on the first amorphous silicon thin film layer. In order to form the first amorphous silicon thin film layer, a first intrinsic silicon thin film layer is formed on the first surface and a first low concentration silicon thin film layer including the second conductive type is formed on the first intrinsic silicon thin film layer. Then, a second intrinsic silicon thin film layer is formed on the first low concentration silicon thin film layer.

According to an exemplary embodiment, a method of manufacturing a solar cell is provided as follows. A first amorphous silicon thin film layer is formed on a first surface of a semiconductor substrate including a first conductive type and a second amorphous silicon thin film layer including a second conductive type is formed on the first amorphous silicon thin film layer. In order to form the first amorphous silicon thin film layer, a source intrinsic silicon thin film layer is formed on the semiconductor substrate. Then, a dopant is injected into the source intrinsic silicon thin film layer in order to separate the source intrinsic silicon thin film layer into a low concentration silicon thin film layer into which the dopant is injected and a first intrinsic silicon thin film layer disposed under the low concentration silicon thin film layer. After that, a second intrinsic silicon thin film layer is formed on the low concentration silicon thin film layer.

According to the above, in an exemplary embodiment, resistance of the amorphous silicon thin film layer disposed between the p-type semiconductor and the n-type semiconductor may be reduced by the low concentration silicon thin film layer arranged in the amorphous silicon thin film layer. Therefore, a current density of the solar cell increases to improve the photoelectric conversion efficiency of the solar cell. In addition, loss of an open circuit voltage of the solar cell may be effectively prevented since the thickness of the amorphous silicon thin film layer is not required to be decreased.

### BRIEF DESCRIPTION OF THE DRAWINGS

The above and other aspects, advantages and features of the present invention will become more readily apparent by reference to the following detailed description when considered in conjunction with the accompanying drawings wherein:

FIG. 1 is cross-sectional view showing an exemplary embodiment of a solar cell according to the present invention;

FIG. 2 is a cross-sectional view showing another exemplary embodiment of a solar cell according to the present invention;

FIG. 3 is a cross-sectional view showing yet another exemplary embodiment of a solar cell according to the present invention;

FIGS. 4A to 4F are views showing an exemplary embodiment of a method of manufacturing a first amorphous silicon thin film layer and a third amorphous silicon thin film layer of the solar cell shown in FIG. 2; and

FIGS. 5A to 5B are views showing an exemplary embodiment of a method of manufacturing a first intrinsic silicon thin film layer and a first low concentration silicon thin film layer of the solar cell shown in FIG. 2.

### DETAILED DESCRIPTION OF THE INVENTION

The invention now will be described more fully hereinafter with reference to the accompanying drawings, in which various embodiments are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, then elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

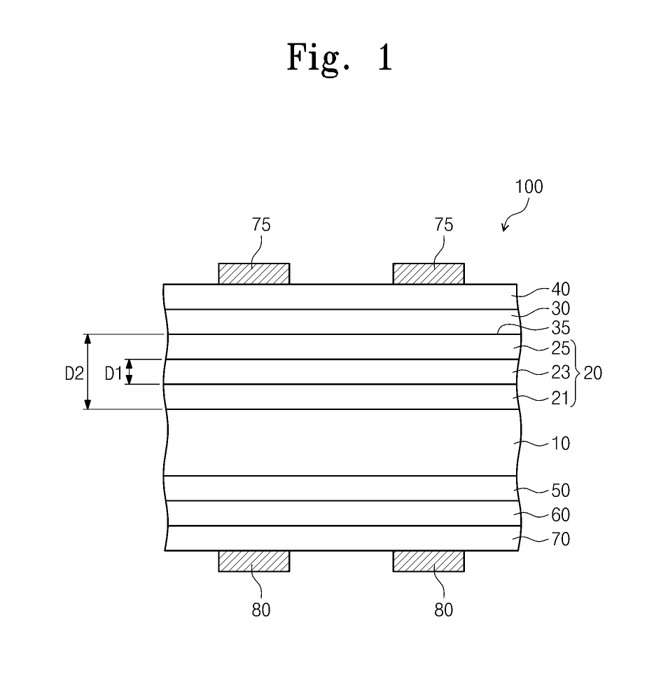

FIG. 1 is cross-sectional view showing an exemplary embodiment of a solar cell according to the present invention.

Referring to FIG. 1, a solar cell 100 includes an n-type semiconductor substrate 10, a first amorphous silicon thin film layer 20, a p-type second amorphous silicon thin film layer 30, a first conductive layer 40, a first electrode 75, a third amorphous silicon thin film layer 50, a fourth amorphous silicon thin film layer 60, a second conductive layer 70 and a second electrode 80.

A p-n junction is formed by the semiconductor substrate 10 and the second amorphous silicon thin film layer 30. In order to cause a photoelectric effect, the semiconductor substrate 10, the first amorphous silicon thin film layer 20 and the second amorphous silicon thin film layer 30 absorb solar energy provided from an external source. Subsequently, according to an electric field generated by the p-n junction, the occurrence of the photoelectric effect enables the electrons to move from the second amorphous silicon thin film layer 30 to the semiconductor substrate 10 and the holes to move from the semiconductor substrate 10 to the second amorphous silicon thin film layer 30. When the first electrode 75 and the second electrode 80 have different polarities from each other, the electrons may be provided to an external electrical circuit electrically connected to the first electrode 75 and the second electrode 80.

In the present exemplary embodiment, the semiconductor substrate 10 is the n-type substrate and the second amorphous silicon thin film layer 30 is the p-type layer. In an alternative exemplary embodiment, the semiconductor substrate 10 may be a p-type substrate and the second semiconductor amorphous silicon thin film layer 30 may be an n-type layer.

Also, in the present exemplary embodiment, the semiconductor substrate 10 may include a single-crystalline silicon. In an alternative exemplary embodiment, the semiconductor substrate 10 may be a substrate including a polycrystalline silicon or a non-crystalline silicon.

In FIG. 1, for the convenience of explanation, silicon thin film layers disposed on the semiconductor substrate 10 have the same thickness except for the semiconductor substrate 10, however the silicon thin film layers may have different thicknesses from each other. In an exemplary embodiment, the first amorphous silicon thin film layer 20 includes a first intrinsic silicon thin film layer 21, a first low concentration silicon thin film layer 23 and a second intrinsic silicon thin film layer 25, all of which may have substantially the same thickness as the fourth amorphous silicon thin film layer 50.

The first amorphous silicon thin film layer 20 is disposed between the semiconductor substrate 10 and the second amorphous silicon thin film layer 30. The first amorphous silicon thin film layer 20 includes the first intrinsic silicon thin film layer 21, the first low concentration silicon thin film layer 23 and the second intrinsic silicon thin film layer 25. As exemplarily shown in FIG. 1, the first intrinsic silicon thin film layer 21 includes an intrinsic non-crystalline silicon and is disposed on the semiconductor substrate 10, the second intrinsic silicon thin film layer 25 includes an intrinsic non-crystalline silicon and is disposed under the second amorphous silicon thin film layer 30 and the first low concentration silicon thin film layer 23 is disposed between the first intrinsic silicon thin film layer 21 and the second intrinsic silicon thin film layer 25.

In the present exemplary embodiment, the first low concentration silicon thin film layer 23 may have a first thickness D1 of about 5 angstroms to about 30 angstroms. In addition, the first amorphous silicon thin film layer 20 may have a second thickness D2 thicker than the first thickness D1 and the second thickness D2 may be in a range of about 20 angstroms to about 100 angstroms.

At times when the semiconductor substrate 10 includes the single-crystalline silicon and the second amorphous silicon thin film layer 30 includes the non-crystalline silicon, a defect density caused by a dangling bond formed at an interface between the single-crystalline silicon and the non-crystalline silicon may cause a deterioration in a photoelectric conversion efficiency of the solar cell 100. However, according to the present exemplary embodiment shown in FIG. 1, since the first amorphous silicon thin film layer 20 includes the first intrinsic silicon thin film layer 21 and the second intrinsic silicon thin film layer 25 respectively corresponding to the semiconductor substrate 10 and the second amorphous silicon thin film layer 30, the defect density is substantially reduced and/or effectively minimized by the first intrinsic silicon thin film layer 21 and the second intrinsic silicon thin film layers 25. The defect density reduction improves the photoelectric conversion efficiency of the solar cell 100.

The first low concentration silicon thin film layer 23 is disposed between the first intrinsic silicon thin film layer 21 and the second intrinsic silicon thin film layer 25 in order to be spaced apart from a first interface 35. The first interface 35 is disposed between the first amorphous silicon thin film layer 20 and the second amorphous silicon thin film layer 30. As exemplarily shown in FIG. 1, if the semiconductor substrate 10 has n-type characteristics and the second amorphous silicon thin film layer 30 has p-type characteristics, then the first low concentration silicon thin film layer 23 has p-type characteristics.

In addition, the first low concentration silicon thin film layer 23 has a dopant concentration that is lower than the second amorphous silicon thin film layer 30. More particularly, if the first low concentration silicon thin film layer 23 and the second amorphous silicon thin film layer 30 are doped with a p-type dopant, such as boron, then the first low concentration silicon thin film layer 23 has a dopant concentration of about 5×10¹⁸ atoms per centimeter cubed (atoms/cm³) to about 5×10²¹ atoms/cm³ and the second amorphous silicon thin film layer 30 has a dopant concentration of about 1×10²¹ atoms/cm³.

Generally, in a solar cell including a p-type semiconductor layer, an n-type semiconductor layer and an intrinsic silicon thin film layer disposed between the p-type semiconductor layer and the n-type semiconductor layer, lifetime of a carrier layer, which improves an open circuit voltage of the solar cell, increases as the thickness of the intrinsic silicon thin film layer increases. The increase in the thickness of the intrinsic silicon thin film layer enhances the photoelectric conversion efficiency of the solar cell. However, since the intrinsic silicon thin film layer has resistance higher than the p-type semiconductor layer and the n-type semiconductor layer, a current density of the solar cell 100 may decrease as the thickness of the intrinsic silicon thin film layer increases.

However, according to the present exemplary embodiment shown in FIG. 1, since the first amorphous silicon thin film layer 20 includes the first low concentration silicon thin film layer 23 doped with the p-type dopant, the resistance of the first amorphous silicon thin film layer 20 is substantially reduced and/or effectively minimized in relation to the first amorphous silicon thin film layer 20, which includes only the first intrinsic silicon thin film layer 21 and the second intrinsic silicon thin film layer 25. Therefore, the reduction of resistance of the first amorphous silicon thin film layer 20 improves the current density of the solar cell 100. Also, since the thickness of both, the first intrinsic silicon thin film layer 21 and the second intrinsic silicon thin film layer 25, is not required to be decreased in order to reduce the resistance of the first amorphous silicon thin film layer 20, the loss of the open circuit voltage is effectively prevented.

If the solar cell 100 does not include the first low concentration silicon thin film layer 23 and includes only the first and second intrinsic silicon thin film layers 21 and 25, then the solar cell 100 has current density of about 34.5 milliamperes per centimeter squared (mA/cm²). a fill factor of about 71.8% and photoelectric conversion efficiency of about 16.85%. However, according to the present exemplary embodiment shown in FIG. 1, if the solar cell 100 includes the first low concentration silicon thin film layer 23 and the first intrinsic silicon thin film layer 21 and the second intrinsic silicon thin film layer 25, then the solar cell 100 improves current density to about 34.7mA/cm², improves fill factor to about 72.9% and improves photoelectric conversion efficiency to about 17.18%. These improvements occur even though the open circuit voltage related to the thickness of the first intrinsic silicon thin film layer 21 and the second intrinsic silicon thin film layer 25 are similar to the open circuit voltage of the previously described solar cell.

The second amorphous silicon thin film layer 30 is arranged on the first amorphous silicon thin film layer 20. In the present exemplary embodiment described with reference to FIG. 1, the second amorphous silicon thin film layer 30 includes a non-crystalline silicon doped with a p-type dopant, such as boron, in order to include the p-type semiconductor characteristics.

The first conductive layer 40 is disposed on the second amorphous silicon thin film layer 30. In the present exemplary embodiment, the first conductive layer 40 is manufactured out of a transparent conductive material, such as indium tin oxide or indium zinc oxide, in order that a light from an exterior source is easily provided to the semiconductor substrate 10, the first amorphous silicon thin film layer 20 and the second amorphous silicon thin film layer 30.

The third amorphous silicon thin film layer 50 is arranged on a rear surface of the semiconductor substrate 10 in order to face the first amorphous silicon thin film layer 20, while simultaneously interposing the semiconductor substrate 10 therebetween. The third amorphous silicon thin film layer 50 includes an intrinsic non-crystalline silicon. Accordingly, the presence of the third amorphous silicon thin film layer 50 decreases defect density between the semiconductor substrate 10 and the fourth amorphous silicon thin film layer 60 and improves the photoelectric conversion efficiency of the solar cell 100. In an exemplary embodiment, the third amorphous silicon thin film layer 50 has a thickness of about 20 angstroms to about 100 angstroms.

The fourth amorphous silicon thin film layer 60 faces the semiconductor substrate 10, while simultaneously interposing the third amorphous silicon thin film layer 50 therebetween. In the present exemplary embodiment, the fourth amorphous silicon thin film layer 60 may include an n+-type non-crystalline silicon that has more of the n-type dopant, such as phosphorus (P), than the semiconductor substrate 10. As a result, the fourth amorphous silicon thin film layer 60 may serve as a back surface field (“BSF”) and improve electron collection.

The second conductive layer 70 is arranged on the fourth amorphous silicon thin film layer 60. The second conductive layer 70 may be manufactured out of a transparent conductive material similar to the first conductive layer 40. However, the second conductive layer 70 may include a metal material, such as aluminum, in order to improve re-absorption of the light by the semiconductor substrate 10, the first amorphous silicon thin film layer 20 and the second amorphous silicon thin film layer 30.

The first electrode 75 is disposed on the first conductive layer 40 in order to be electrically connected to the first conductive layer 40. The second electrode 80 is disposed on the second conductive layer 70 in order to be electrically connected to the second conductive layer 70. The first electrode 75 and the second electrode 80 may be electrically connected to an external circuit. The electrical current generated by the solar cell 100 may be provided to the external circuit through the first electrode 75 and the second electrode 80.

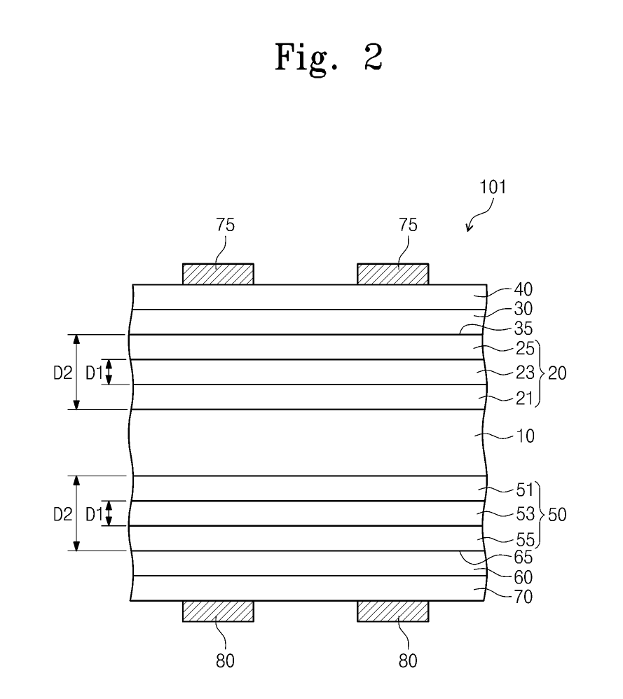

FIG. 2 is a cross-sectional view showing another exemplary embodiment of a solar cell according to the present invention. A difference between the solar cell 100 shown in FIG. 1 and a solar cell 101 shown in FIG. 2 is the presence of a third amorphous silicon thin film layer 50, which includes a plurality of silicon thin film layers. Thus, the third amorphous silicon thin film layer 50 is subsequently described. In addition, in reference to the subsequent description of FIG. 2, the same reference numerals denote the same elements as in FIG. 1 and thus the detailed descriptions of the same elements are omitted.

Referring to FIG. 2, the solar cell 101 includes a semiconductor substrate 10, a first amorphous silicon thin film layer 20, a second amorphous silicon thin film layer 30, a first conductive layer 40, a first electrode 75, a third amorphous silicon thin film layer 50, a fourth amorphous silicon thin film layer 60, a second conductive layer 70 and a second electrode 80.

In addition, the first amorphous silicon thin film layer 20 includes a first intrinsic silicon thin film layer 21, a first low concentration silicon thin film layer 23 and a second intrinsic silicon thin film layer 25. In the present exemplary embodiment, the semiconductor substrate 10 may include an n-type single-crystalline crystal silicon. Further, the second amorphous silicon thin film layer 30 and the first low concentration silicon thin film layer 23 may include a p-type non-crystalline silicon. Moreover, the first intrinsic silicon thin film layer 21 and the second intrinsic silicon thin film layer 25 include an intrinsic non-crystalline silicon.

The third amorphous silicon thin film layer 50 includes a third intrinsic silicon thin film layer 51, a fourth intrinsic silicon thin film layer 55 and a second low concentration silicon thin film layer 53. The second low concentration silicon thin film layer 53 is disposed between the third intrinsic silicon thin film layer 51 and the fourth intrinsic silicon thin film layer 55. Similar to the third amorphous silicon thin film layer 50 as shown and described in reference to FIG. 1, the presence of the third intrinsic silicon thin film layer 51 and the fourth intrinsic silicon thin film layer 55 may substantially reduce and/or effectively minimize the defect density between the semiconductor substrate 10 and the fourth amorphous silicon thin film layer 60. The defect density reduction between the semiconductor substrate 10 and the fourth amorphous silicon thin film layer 60 thus enhances the photoelectric conversion efficiency of the solar cell 101.

In an alternative exemplary embodiment, the second low concentration silicon thin film layer 53 is disposed between the third intrinsic silicon thin film layer 51 and the fourth intrinsic silicon thin film layer 55. This structure enables the second low concentration silicon thin film layer 53 to be spaced apart from a second interface 65, which is disposed between the third amorphous silicon thin film layer 50 and the fourth amorphous silicon thin film layer 60. As exemplarily shown in FIG. 2, if the semiconductor substrate 10 has n-type semiconductor characteristics and the fourth amorphous silicon thin film layer 60 has n+-type semiconductor characteristics, then the second low concentration silicon thin film layer 53 has n-type semiconductor characteristics.

In an exemplary embodiment, the second low concentration silicon thin film layer 53 has a dopant concentration that is lower than the second amorphous silicon thin film layer 30 or the fourth amorphous silicon thin film layer 60. More particularly, if, in order to obtain n-type semiconductor characteristics, the second low concentration silicon thin film layer 53 and the fourth amorphous silicon thin film layer 60 are doped with an n-type dopant, such as phosphorus (P), then the second low concentration silicon thin film layer 53 has a dopant concentration of about 5×10¹⁸ atoms/cm³ to about 5×10²⁰ atoms/cm³. Also then, the second amorphous silicon thin film layer 30 and the fourth amorphous silicon thin film layer 60 have a dopant concentration of about 1×10²¹ atoms/cm³.

In an exemplary embodiment, similar to the first thickness D1 of the first low concentration silicon thin film layer 23, the second low concentration silicon thin film layer 53 has a thickness of about 5 angstroms to about 30 angstroms. In an alternative exemplary embodiment, similar to the second thickness D2 of the first amorphous silicon thin film layer 20, the third amorphous silicon thin film layer 50 has a thickness of about 20 angstroms to about 100 angstroms, which is thicker than the second low concentration silicon thin film layer 53.

As described above, when the third amorphous silicon thin film layer 50 includes the second low concentration silicon thin film layer 53, then the resistance of the third amorphous silicon thin film layer 50 is substantially reduced and/or effectively minimized in relation to the third amorphous silicon thin film layer 50, which includes only the third intrinsic silicon thin film layer 51 and the fourth intrinsic silicon thin film layer 55.

Therefore, similar to the first low concentration silicon thin film layer 23 shown and described with reference to FIG. 1, the resistance of the third amorphous silicon thin film layer 50 is substantially reduced and/or effectively minimized without substantially reducing and/or effectively minimizing the thickness of the third intrinsic silicon thin film layer 51 and the fourth intrinsic silicon thin film layer 55. Hence, the substantial reduction and/or effective minimization in resistance of the third amorphous silicon thin film layer 50 effectively prevents the loss of the open circuit voltage of the solar cell 101.

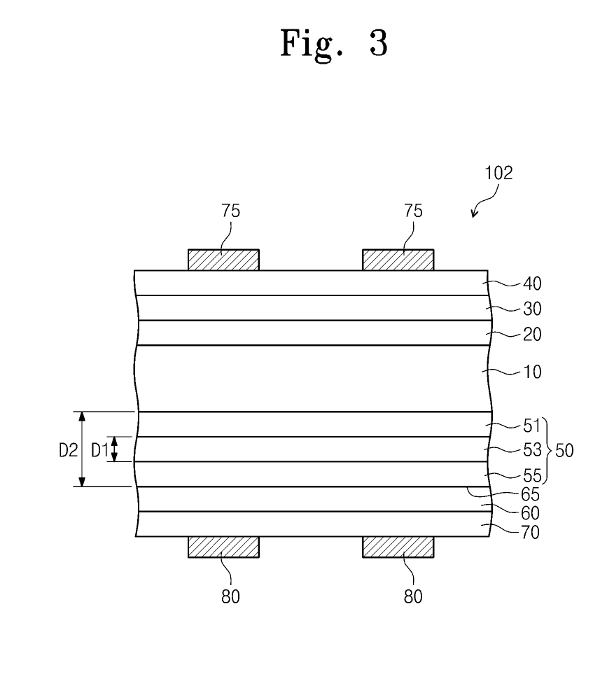

FIG. 3 is a cross-sectional view showing yet another exemplary embodiment of a solar cell according to the present invention. A difference between the solar cell 100 shown in FIG. 1, the solar cell 101 shown in FIG. 2 and the solar cell 102 shown in FIG. 3 is that within the solar cell 102 a first amorphous silicon thin film layer 20 has a single-layer structure and a third amorphous silicon thin film layer 50 includes a multi-layer structure as shown in FIG. 2. Thus, subsequently described in reference to FIG. 3 are the first amorphous silicon thin film layer 20 and the third amorphous silicon thin film layer 50. In addition, in reference to the subsequent description of FIG. 3, the same reference numerals denote the same elements in as FIG. 1 and FIG. 2 and thus the detailed descriptions of the same elements are omitted.

Referring to FIG. 3, a solar cell 102 includes a semiconductor substrate 10, a first amorphous silicon thin film layer 20, a second amorphous silicon thin film layer 30, a first conductive layer 40, a first electrode 75, the third amorphous silicon thin film layer 50, a fourth amorphous silicon thin film layer 60, a second conductive layer 70 and a second electrode 80. A second interface 65 is disposed between the third amorphous silicon thin film layer 50 and the fourth amorphous silicon thin film layer 60.

The first amorphous silicon thin film layer 20 is disposed on the semiconductor substrate 10. To improve a photoelectric conversion efficiency of the solar cell 102, the first amorphous silicon thin film layer 20 includes an intrinsic non-crystalline silicon and substantially reduces and/or effectively minimizes defect density between the semiconductor substrate 10 and the second amorphous silicon thin film layer 30. In the present exemplary embodiment, the first amorphous silicon thin film layer 20 may have a thickness of about 20 angstroms to about 100 angstroms.

The third amorphous silicon thin film layer 50 includes a third intrinsic silicon thin film layer 51, a fourth intrinsic silicon thin film layer 55. A second low concentration silicon thin film layer 53 is disposed between the third intrinsic silicon thin film layer 51 and the fourth intrinsic silicon thin film layer 55. As exemplarily shown in FIG. 2, when the semiconductor substrate 10 has n-type semiconductor characteristics and the fourth amorphous silicon thin film layer 60 has n+-type semiconductor characteristics, then the second low concentration silicon thin film layer 53 has n-type semiconductor characteristics.

In an exemplary embodiment, similar to the first thickness D1 of the first low concentration silicon thin film layer 23 exemplarily shown in FIG. 1 and FIG. 2, the second low concentration silicon thin film layer 53 has a thickness of about 5 angstroms to about 30 angstroms. In an alternative exemplary embodiment, similar to the second thickness D2 of the first amorphous silicon thin film layer 20 shown in FIG. 1 and FIG. 2, the third amorphous silicon thin film layer 50 may have a thickness of about 20 angstroms to about 100 angstroms, which is thicker than the second low concentration silicon thin film layer 53.

According to the present exemplary embodiment shown in FIG. 3, since the third amorphous silicon thin film layer 50 includes the second low concentration silicon thin film layer 53, the resistance of the third amorphous silicon thin film layer 50 is substantially reduced and/or effectively minimized by dopants doped in the second low concentration silicon thin film layer 53. Therefore, the current density of the solar cell 102 is improved. The improvement of the current density of the solar cell 102 thereby increases the photoelectric conversion efficiency of the solar cell 102.

In addition, in order to reduce the resistance of the third amorphous silicon thin film layer 50, the thickness of the third intrinsic silicon thin film layer 51 and the fourth intrinsic silicon thin film layer 55 does not need to be decreased. As a result, the loss of open circuit voltage of the solar cell 102 is effectively prevented.

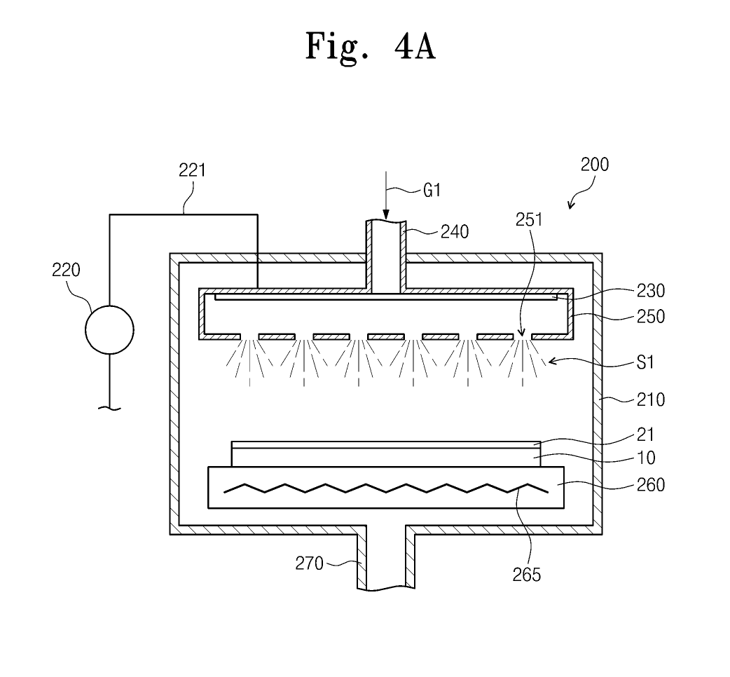

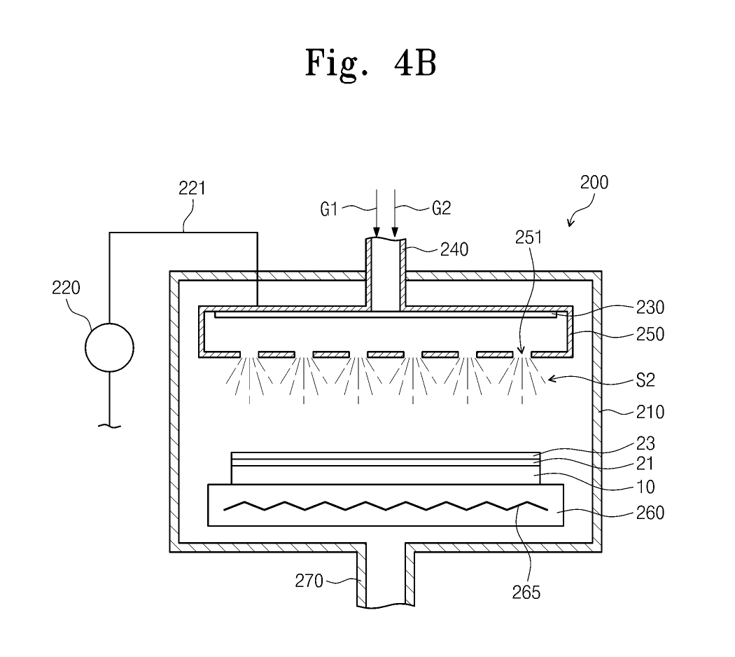

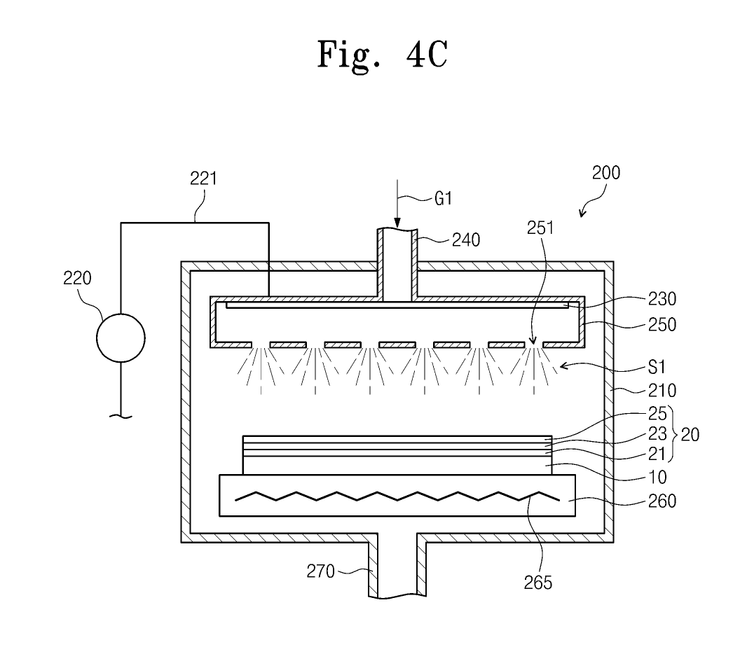

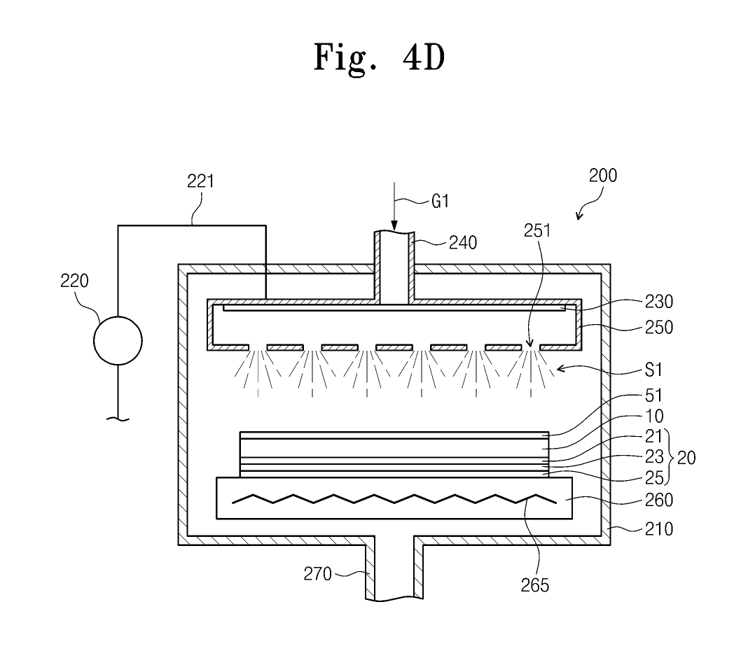

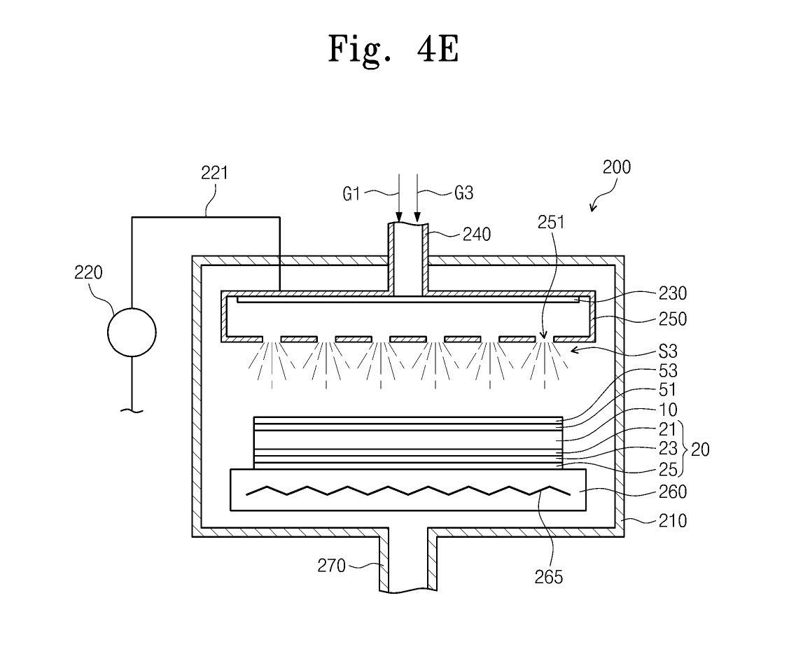

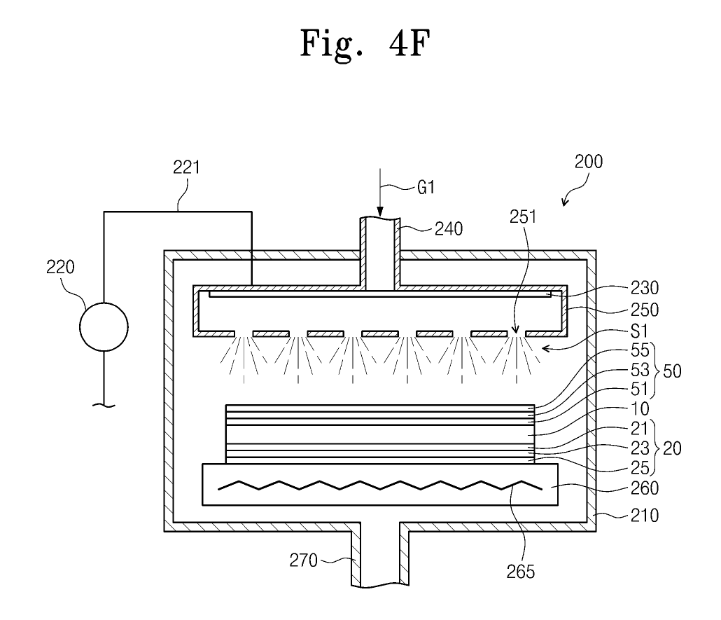

FIGS. 4A to 4F are views showing an exemplary embodiment of a method of manufacturing the first amorphous silicon thin film layer and the third amorphous silicon thin film layer of the solar cell shown in FIG. 2. In FIGS. 4A to 4F, the same reference numerals denote the same elements in FIGS. 1 and 2 and detailed descriptions of the same elements is omitted.

Referring to FIG. 4A, a plasma-enhanced chemical-vapor-deposition (“PECVD”) equipment 200 includes a chamber 210 including a space therein, an electric power supply 220, a discharge electrode 230, a plasma generator 250, a gas inlet 240, a gas outlet 270, a substrate supporter 260 and a heating member 265.

The electric power supply 220 is electrically connected to the discharge electrode 230 through an electric power supply line 221. The discharge electrode 230 is contained within the plasma generator 250. The discharge electrode 230, powered by the electric power supply 220, applies radio frequency power to create a plasma of ionized gas. The plasma generator 250 is connected to the gas inlet 240, which receives a first reaction gas G1 through the gas inlet 240.

The first reaction gas G1 provided to the plasma generator 250 via the gas inlet 240 is plasmanized by the radio frequency power in order to be a first deposition source S1. The first deposition source S1 is deposited onto the semiconductor substrate 10 via a gas flow exit 251 of the plasma generator 250.

The substrate supporter 260 supports the semiconductor substrate 10. The heating member 265 is contained within the substrate supporter 260. In order to make the deposition source S1 easily depositable onto the semiconductor substrate 10, the heating member 265 heats the semiconductor substrate 10, while the deposition source S1 is deposited on the semiconductor substrate 10. Also, reaction gases contained in the chamber 210 may be exhausted through the gas outlet 270.

FIG. 4A shows an exemplary embodiment of a method of forming the first intrinsic silicon thin film layer 21 on the semiconductor substrate 10 using the PECVD equipment 200. In the present exemplary embodiment, the first reaction gas G1 used to form the first intrinsic silicon thin film layer 21 on the semiconductor substrate 10 includes silane gas (SiH₄) and hydrogen gas (H₂) and a flow ratio of the silane gas to the hydrogen gas is about 1:4. More particularly, in order to form the first intrinsic silicon thin film layer 21 of the thickness of about 20 angstroms, the silane gas is provided to the plasma generator 250 at a rate of about 100 standard cubic centimeter per minute (“sccm”) during about 20 seconds and the hydrogen gas is provided to the plasma generator 250 at a rate of about 400 sccm during about 20 seconds.

As described above, when the first reaction gas G1 is provided to the plasma generator 250, then the first reaction gas G1 is plasmanized by the discharge electrode 230 in order to form the first deposition source S1. The first deposition source S1 is then deposited onto the semiconductor substrate 10 in order to form the first intrinsic silicon thin film layer 21.

Referring to FIG. 4B, after the first intrinsic silicon thin film layer 21 is formed on the semiconductor substrate 10, a second reaction gas G2 is further provided to the plasma generator 250.

In the present exemplary embodiment shown in FIG. 4B, the second reaction gas G2 includes a diborane gas (B₂H₆). In addition, when the silane gas in the first reaction gas G1 is provided to the plasma generator 250 in a flow rate of about 100 sccm and the hydrogen gas in the first reaction gas G1 is provided to the plasma generator 250 in a flow rate of about 400 sccm, then the second reaction gas G2 is substantially simultaneously provided to the plasma generator 250 in a flow rate of about 1 sccm.

As described above, the first reaction gas G1 and the second reaction gas G2 provided to the plasma generator 250 are plasmanized to form a second deposition gas S2, which is deposited onto the first intrinsic silicon thin film layer 21. The second deposition gas S2 exits through the gas flow exit 251 and forms the first low concentration silicon thin film layer 23. In addition, since the second reaction gas G2 is provided to the plasma generator 250 in the flow rate of about 1 sccm, the first low concentration silicon thin film layer 23 is formed at a rate of about 1 angstrom per second (angstrom/second). As a result, the first low concentration silicon thin film layer 23 is easily formed to have the thickness of about 5 angstroms to about 30 angstroms.

In an exemplary embodiment, when the process of forming the first intrinsic silicon thin film layer 21 described with reference to FIG. 4A is referred to as a first process and the process of forming the first low concentration silicon thin film layer 23 described with reference to FIG. 4B is referred to as a second process, then the first process and the second process can be successively performed in the chamber 210.

The first process and the second process can be successively performed because, during the first process and the second process, the electric power supply 220 is maintained at an ON state without alternating between an ON state and an OFF state in order to provide the radio frequency power to the discharge electrode 230. Therefore, the electric power supply 220 is continuously maintained at the ON state between the timing when the first process is finished and the timing when the second process begins. The continuous maintenance of the ON state thus enables the successive formation of the first low concentration silicon thin film layer 23 over the first intrinsic silicon thin film layer 21.

Next, after the first process is completed, the first reaction gas G1 is continuously provided to the plasma generator 250. More particularly, during the first process and the second process, the first reaction gas G1 is continuously provided to the plasma generator 250 without being stopped. In addition, the second reaction gas G2 is substantially simultaneously provided to the plasma generator 250 together with the first reaction gas G1 from the timing when the second process begins. Thus, by controlling the flow of gas provided to the plasma generator 250, the first intrinsic silicon thin film layer 21 and the first low concentration silicon thin film layer 23 are successively formed on the semiconductor substrate 10. The control of the gas flow thereby enables immediate formation of the first intrinsic silicon thin film layer 21 and the first low concentration silicon thin film layer 23.

Referring to FIG. 4C, after the first intrinsic silicon thin film layer 21 and the first low concentration silicon thin film layer 23 are formed on the semiconductor substrate 10, the first reaction gas G1 is provided to the plasma generator 250. The first reaction gas G1 provision is performed in order to form a second intrinsic silicon thin film layer 25 on the first low concentration silicon thin film layer 23 through the same process previously applied to form the first intrinsic silicon thin film layer 21 described with reference to FIG. 4A.

Referring again to FIG. 4B, when the process of forming the second intrinsic silicon thin film layer 25 is referred to as a third process, then the second process previously described with reference to FIG. 4B and the third process are successively performed. More particularly, during the second process and the third process, the electric power supply 220 is continuously maintained at the ON state thereby applying the radio frequency power to the plasma generator 250 during the second process and the third process.

In addition, after the second process is completed, the first reaction gas G1 is continuously provided to the plasma generator 250 during the second process and the third process. The second gas G2 is provided to the plasma generator 250 from the time when the second process begins. The supply of the second reaction gas G2 stops at the time when the third process begins. Therefore, by controlling the flow of gas to the plasma generator 250, the first low concentration silicon thin film layer 23 and the second intrinsic silicon thin film layer 25 are successively formed on the semiconductor substrate 10. Thus, the control of gas flow thereby enables continuous formation of the first low concentration silicon thin film layer 23 and the second intrinsic silicon thin film layer 25 between the second process and the third process.

The first process and the second process are successively performed as described with reference to FIG. 4B and the second process and the third process are successively performed as described with reference to FIG. 4C. Thus, the first process, the second process and the third process are successively performed, so that the first intrinsic silicon thin film layer 21, the first low concentration silicon thin film layer 23 and the second intrinsic silicon thin film layer 25 are continuously formed.

In an exemplary embodiment, when the method of forming the first intrinsic silicon thin film layer 21, the first low concentration silicon thin film layer 23 and the second intrinsic silicon thin film layer 25 described with reference to FIGS. 4A to 4C is referred to as a first method, then the first intrinsic silicon thin film layer 21, the first low concentration silicon thin film layer 23 and the second intrinsic silicon thin film layer 25 are formed by a second method, which is different from the first method.

Hereinafter, the second method will be described in detail with reference to FIGS. 4D to 4F.

First, the first intrinsic silicon thin film layer 21 is formed on the semiconductor substrate 10 using the process as shown in FIG. 4A when the electric power supply 220 is turned off. Then, while the electric power source part 220 is maintained in the OFF state, the first reaction gas G1 and the second reaction gas G2 are provided to the plasma generator 250. Next, when the electric power supply 220 is turned on, the first reaction gas G1 and the second reaction gas G2 are plasmanized in order that the first low concentration silicon thin film layer 23 are formed on the first intrinsic silicon thin film layer 21.

Referring to FIG. 4D, after the first intrinsic silicon thin film layer 21, the first low concentration silicon thin film layer 23 and the second intrinsic silicon thin film layer 25 are formed on the semiconductor substrate 10, the semiconductor substrate 10 is turned upside down in order that a rear surface of the semiconductor substrate 10 is upwardly exposed and the second intrinsic silicon thin film layer 25 makes contact with the substrate supporter 260. Then, the third intrinsic silicon thin film layer 51 is formed on the rear surface of the semiconductor substrate 10 using the first reaction gas G1 through the process described with reference to FIG. 4A.

Referring to FIG. 4E, after the third intrinsic silicon thin film layer 51 is formed on the semiconductor substrate 10, in addition to the first reaction gas G1, a third reaction gas G3 is further provided to the plasma generator 250.

In the present exemplary embodiment shown in FIG. 4E, the third reaction gas G3 includes phosphine gas (PH₃). Also, when the silane gas included in the first reaction gas G1 is provided to the plasma generator 250 in the flow rate of about 100 sccm and the hydrogen gas included in the first reaction gas G1 is provided to the plasma generator 250 in the flow rate of about 400 sccm, then the third reaction gas G3 is provided to the plasma generator 250 in the flow rate of about 1 sccm.

The first reaction gas G1 and the third reaction gas G3 provided via the gas inlet 240 to the plasma generator 250 are plasmanized to form a third deposition source S3. As a result, the third deposition source S3 is deposited onto the third intrinsic silicon thin film layer 51 as the second low concentration silicon thin film layer 53.

Referring to FIG. 4F, after the third intrinsic silicon thin film layer 51 and the second low concentration silicon thin film layer 53 are sequentially formed on the rear surface of the semiconductor substrate 10 in a process similar to the process of forming the third intrinsic silicon thin film layer 51 described with reference to FIG. 4D, the fourth intrinsic silicon thin film layer 55 is formed on the second low concentration silicon thin film layer 53 using the first reaction gas G1.

When the process of forming the third intrinsic silicon thin film layer 51 described with reference to FIG. 4D is referred to as a fourth process, then the process of forming the second low concentration silicon thin film layer 53 described with reference to FIG. 4E is referred to as a fifth process and the process of forming the fourth intrinsic silicon thin film layer 55 described with reference to FIG. 4F is referred to as a sixth process. The fourth process, the fifth process and the sixth process are successively performed without any time delay similarly to the first process, the second process and the third process, as described with reference to FIGS. 4A to 4C.

In an exemplary embodiment, when the second amorphous silicon thin film layer 30, the first conductive layer 40 and the first electrode 75 are positioned as illustrated in FIG. 2, i.e., on the first amorphous silicon thin film layer 20, and when the fourth amorphous silicon thin film layer 60, the second conductive layer 70 and the second electrode 80 are positioned as illustrated in FIG. 2, i.e., on the third amorphous silicon thin film layer 50, then the solar cell 101 shown in FIG. 2 can be completely manufactured.

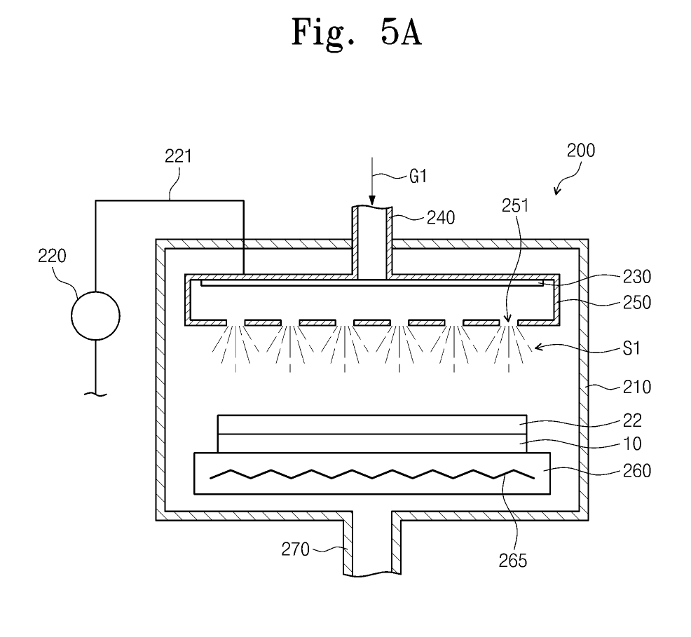

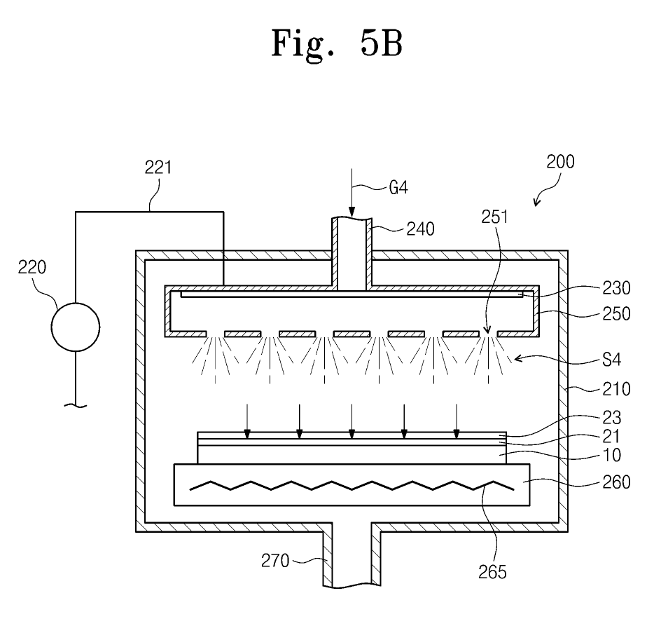

FIGS. 5A to 5B are diagrams showing an exemplary embodiment of a method of manufacturing the first intrinsic silicon thin film layer and the first low concentration silicon thin film layer of the solar cell 101 shown in FIG. 2.

Referring to FIGS. 5A and 5B, a source intrinsic silicon thin film layer 22 is formed on a semiconductor substrate 10 using the PECVD equipment 200 described with reference to FIG. 4A. The source intrinsic silicon thin film layer 22 is formed by the process similar to the process used to form the first intrinsic silicon thin film layer 21 as shown and described with reference to FIG. 4A. However, the source intrinsic silicon thin film layer 22 is thicker than the first intrinsic silicon thin film layer 21.

A fourth reaction gas G4 is provided to a plasma generator 250. According to the present exemplary embodiment shown in FIG. 5B, the fourth reaction gas G4 includes hydrogen gas (H₂) and diborane gas (B₂H₆). When the fourth reaction gas G4 is plasmanized, boron ions react with the surface of the source intrinsic silicon thin film layer 22. As a result, the boron ions are diffused to a predetermined depth from the surface of the source intrinsic silicon thin film layer 22. This diffusion thereby enables doping of the source intrinsic silicon thin film layer 22 with the boron ions.

After the boron ion doping process is completed, the source intrinsic silicon thin film layer 22 is divided into two layers. One layer includes the first low concentration silicon thin film layer 23 in which the boron ions are doped and another layer includes the first intrinsic silicon thin film layer 21 in which the boron ions are not doped.

According to the exemplary process of forming the first intrinsic silicon thin film layer 21 and the first low concentration silicon thin film layer 23, the thickness of the source intrinsic silicon thin film layer 22 is equal to a sum of the thickness of the first intrinsic silicon thin film layer 21 and the thickness of the first low concentration silicon thin film layer 23. In addition, the source intrinsic silicon thin film layer 22 and the first intrinsic silicon thin film layer 21 possess the same intrinsic semiconductor characteristics. However, since a portion of the source intrinsic silicon thin film layer 22 becomes the first low concentration silicon thin film layer 23 doped with the dopant, the first low concentration silicon thin film layer 23 is thinner than the source intrinsic silicon thin film layer 22.

In addition, the third intrinsic silicon thin film layer 51 shown in FIG. 2 and the second low concentration silicon thin film layer 53 shown in FIG. 2 are formed by the same process as the process used to form the first intrinsic silicon thin film layer 21 and the first low concentration silicon thin film layer 23, as described with reference to FIGS. 5A and 5B.

Although many exemplary embodiments of the present invention have been described, a skilled artisan understands that the present invention is not limited to these exemplary embodiments. Rather, various changes and modifications can be made by one ordinary skilled in the art within the spirit and scope of the present invention as hereinafter claimed.

What is claimed is:

1. A solar cell comprising:
a semiconductor substrate including a first conductive type;
a first amorphous silicon thin film layer disposed on the semiconductor substrate;
a second amorphous silicon thin film layer including a second conductive type and disposed on the first amorphous silicon thin film layer,
wherein the first amorphous silicon thin film layer comprises:
a first intrinsic silicon thin film layer;
a second intrinsic silicon thin film layer facing the semiconductor substrate while interposing the first intrinsic silicon thin film layer therebetween; and
a first low concentration silicon thin film layer including the second conductive type and disposed between the first intrinsic silicon thin film layer and the second intrinsic silicon thin film layer.

2. The solar cell of claim 1, further comprising:
a third amorphous silicon thin film layer facing the first amorphous silicon thin film while interposing the semiconductor substrate therebetween; and
a fourth amorphous silicon thin film layer including the first conductive type and facing the semiconductor substrate while interposing the third amorphous silicon thin film layer therebetween, and
wherein the third amorphous silicon thin film comprises:
a third intrinsic silicon thin film layer;
a fourth intrinsic silicon thin film layer disposed between the third intrinsic silicon thin film layer and the fourth amorphous silicon thin film layer; and
a second low concentration silicon thin film layer including the first conductive type and disposed between the third intrinsic silicon thin film layer and the fourth intrinsic silicon thin film layer.

3. The solar cell of claim 2, wherein a concentration of a dopant in each of the first low concentration silicon thin film layer and the second low concentration silicon thin film is lower than the second amorphous silicon thin film layer and the fourth amorphous silicon thin film layer.

4. The solar cell of claim 3, wherein the concentration of the dopant in each of the first low concentration silicon thin film layer and the second low concentration silicon thin film layer is in a range of about 5×10¹⁸ atoms/cm³ to about 5×10²⁰ atoms/cm³.

5. The solar cell of claim 3, wherein the concentration of the dopant in the fourth amorphous silicon thin film layer is higher than the semiconductor substrate.

6. The solar cell of claim 5, wherein
the semiconductor substrate comprises an n-type crystalline silicon,
the second amorphous silicon thin film layer comprises a p-type non-crystalline silicon,
the fourth amorphous silicon thin film layer comprises an n-type non-crystalline silicon,
the first low concentration silicon thin film layer comprises the p-type non-crystalline silicon, and
the second low concentration silicon thin film layer comprises the n-type non-crystalline silicon.

7. The solar cell of claim 5, wherein
the semiconductor substrate comprises a p-type crystalline silicon,
the second amorphous silicon thin film layer comprises an n-type non-crystalline silicon,
the fourth amorphous silicon thin film layer comprises a p-type non-crystalline silicon,
the first low concentration silicon thin film layer comprises the n-type non-crystalline silicon, and
the second low concentration silicon thin film layer comprises the p-type non-crystalline silicon.

8. The solar cell of claim 2, wherein each of the first low concentration silicon thin film layer and the second low concentration silicon thin film layer has a thickness in a range of about 5 angstroms to about 30 angstroms.

9. The solar cell of claim 1, further comprising:
a first conductive layer facing the first amorphous silicon thin film layer while interposing the second amorphous silicon thin film layer therebetween;
a first electrode electrically connected to the first conductive layer;
a second conductive layer facing a third amorphous silicon thin film layer while interposing a fourth amorphous silicon thin film layer therebetween; and
a second electrode electrically connected to the second conductive layer.

10. A method of manufacturing a solar cell, the method comprising:
forming a first amorphous silicon thin film layer on a first surface of a semiconductor substrate including a first conductive type; and
forming a second amorphous silicon thin film layer including a second conductive type on the first amorphous silicon thin film layer,
wherein the forming a first amorphous silicon thin film layer comprises:
forming a first intrinsic silicon thin film layer on the first surface;
forming a first low concentration silicon thin film layer including the second conductive type on the first intrinsic silicon thin film layer; and
forming a second intrinsic silicon thin film layer on the first low concentration silicon thin film layer.

11. The method of claim 10, further comprising:
forming a third amorphous silicon thin film layer on a second surface opposite to the first surface; and
forming a fourth amorphous silicon thin film layer on the third amorphous silicon thin film layer,
wherein the forming a third amorphous silicon thin film layer comprises:
forming a third intrinsic silicon thin film layer on the second surface;
forming a second low concentration silicon thin film layer including the first conductive type on the third intrinsic silicon thin film layer; and
forming a fourth intrinsic silicon thin film layer on the second low concentration silicon thin film layer.

12. The method of claim 11, wherein
the first low concentration silicon thin film layer is doped with a first dopant in order to have a first dopant concentration,
the second low concentration silicon thin film layer is doped with a second dopant in order to have a second dopant concentration, and
each of the second and fourth amorphous silicon thin film layers is doped in order to have a higher dopant concentration than the first and second dopant concentrations.

13. The method of claim 12, wherein each of the first concentration and the second concentration is in a range of about 5×10¹⁸ atoms/cm³ to about 5×10²⁰ atoms/cm³.

14. The method of claim 12, wherein
the first amorphous silicon thin film layer is formed by providing at least one of a first reaction gas or a second reaction gas to a chemical vapor deposition apparatus,
the first reaction gas is provided to the chemical vapor deposition apparatus while the first intrinsic silicon thin film layer, the first low concentration silicon thin film layer and the second intrinsic silicon thin film layer are being formed, and
the second reaction gas is further provided to the chemical vapor deposition apparatus while the first low concentration silicon thin film layer is being formed.

15. The method of claim 14, wherein
the third amorphous silicon thin film layer is formed by providing at least one of the first reaction gas or a third reaction gas to the chemical vapor deposition apparatus,
the first reaction gas is provided to the chemical vapor deposition apparatus while the third intrinsic silicon thin film layer, the second low concentration silicon thin film layer and the fourth intrinsic silicon thin film layer are being formed, and
the third reaction gas is further provided to the chemical vapor deposition apparatus while the second low concentration silicon thin film layer is being formed.

16. The method of claim 15, wherein
the chemical vapor deposition apparatus is a plasma-enhanced chemical-vapor-deposition apparatus,
the semiconductor substrate is an n-type substrate,
the first reaction gas comprises a silane gas (SiH₄) and a hydrogen gas (H₂),
the second reaction gas comprises a p-type dopant,
the third reaction gas comprises an n-type dopant,
a flow ratio of the silane gas, the hydrogen gas and the second reaction gas provided to the chemical vapor deposition apparatus is about 100:400:1 when the first low concentration silicon thin film layer is being formed, and
a flow ratio of the silane gas, the hydrogen gas and the third reaction gas provided to the chemical vapor deposition apparatus is about 100:400:1 when the second low concentration silicon thin film layer is being formed.

17. A method of manufacturing a solar cell, the method comprising:
forming a first amorphous silicon thin film layer on a semiconductor substrate including a first conductive type; and
forming a second amorphous silicon thin film layer including a second conductive type on the first amorphous silicon thin film layer,
wherein the forming a first amorphous silicon thin film layer comprises:
forming a source intrinsic silicon thin film layer on the semiconductor substrate;
injecting a dopant into the source intrinsic silicon thin film layer in order to separate the source intrinsic silicon thin film layer into a low concentration silicon thin film layer into which the dopant is injected and a first intrinsic silicon thin film layer disposed under the low concentration silicon thin film layer; and
forming a second intrinsic silicon thin film layer on the low concentration silicon thin film layer.

18. The method of claim 17, wherein the low concentration silicon thin film layer is doped to have a dopant concentration smaller than the second amorphous silicon thin film layer.

19. The method of claim 18, wherein the dopant concentration of the low concentration silicon thin film layer is in a range of about 5×10¹⁸ atoms/cm³ to about 5×10²⁰ atoms/cm³.
